(19) United States
(12) Patent Application Publication
(10) Pub. No.: US 2026/0198156 A1
(43) Pub. Date: Jul. 9, 2026

(54) DISPLAY DEVICE, METHOD OF MANUFACTURING THE SAME, AND ELECTRONIC DEVICE INCLUDING THE SAME

(71) Applicant: Samsung Display Co., LTD., Yongin-si (KR)

(72) Inventor: Jae Hoon KIM, Yongin-si (KR)

(21) Appl. No.: 19/273,304

(22) Filed: Jul. 18, 2025

(30) Foreign Application Priority Data
Jan. 7, 2025 (KR) 10-2025-0002367

(51) Int. Cl. H10H 29/37; H10H 29/01; H10K 59/12; H10K 59/122; H10K 71/13

(52) U.S. Cl. CPC H10H 29/37; H10H 29/012; H10K 59/1201; H10K 59/122; H10K 71/135

(57) ABSTRACT

A display device includes a substrate, an anode electrode disposed on the substrate, a spacer disposed in a same layer as the anode electrode, and a pixel defining layer defining an opening exposing the anode electrode and covering at least a part of the spacer on the spacer. A liquid repellency of the pixel defining layer is higher than a liquid repellency of the spacer.

This application claims priority to Korean Patent Application Number 10-2025-0002367, filed on January 7, 2025, and all the benefits accruing therefrom under 35 U.S.C. §119, the content of which in its entirety is herein incorporated by reference.

### BACKGROUND

### 1. Field

Embodiments of the disclosure generally relate to a display device, and more particularly, to a display device, a method of manufacturing the same, and an electronic device including the same.

### 2. Description of Related Art

Recently, as interest in information display is increasing, research and development on display devices are continuously being carried out.

### SUMMARY

Embodiments provide a display device with improved reliability.

Embodiments provide a method of manufacturing the display device.

Embodiments provide an electronic device including the display device.

In an embodiment of the disclosure, a display device may include a substrate, an anode electrode disposed on the substrate, a spacer disposed in a same layer as the anode electrode, and a pixel defining layer defining an opening exposing the anode electrode and covering at least a part of the spacer on the spacer, where a liquid repellency of the pixel defining layer is higher than a liquid repellency of the spacer.

In an embodiment, the pixel defining layer may include a first portion overlapping the spacer in a plan view, and a second portion formed integrally with the first portion and having a height less than a height of the spacer.

In an embodiment, a height of the first portion may be less than or equal to a maximum height of the second portion.

In an embodiment, at least a part of a surface of the pixel defining layer may include fluorine.

In an embodiment, an upper surface of the second portion extending from the first portion may have liquid repellency.

In an embodiment, the spacer may be in overall contact with the pixel defining layer.

In an embodiment, the display device may further include a light-emitting layer disposed on the anode electrode and disposed in the opening.

In an embodiment, a distance from the substrate to an upper surface of the spacer may be greater than a distance from the substrate to an upper surface of the light-emitting layer.

In an embodiment of the disclosure, a display device may include a substrate, a pixel defining layer disposed on the substrate, and a spacer disposed on the pixel defining layer and having a width less than a width of the pixel defining layer, where at least a part of a surface of each of the pixel defining layer and the spacer has liquid repellency.

In an embodiment, at least the part of the surface of each of the pixel defining layer and the spacer may include fluorine.

In an embodiment of the disclosure, a method of manufacturing a display device may include forming an anode electrode on a substrate, forming a spacer in the same layer as the anode electrode, and defining an opening exposing the anode electrode and forming a pixel defining layer covering at least a part of the spacer on the spacer, where a liquid repellency of the pixel defining layer is higher than a liquid repellency of the spacer.

In an embodiment, the pixel defining layer includes a first portion and a second portion, and the forming the pixel defining layer may include forming the first portion overlapping the spacer in a plan view, and forming the second portion integrally with the first portion, the second portion having a height less than a height of the spacer and greater than or equal to a height of the first portion.

In an embodiment, the pixel defining layer may include a material including fluorine.

In an embodiment, the forming the pixel defining layer may include forming a preliminary pixel defining layer entirely disposed on the substrate and the spacer.

In an embodiment, a height of the preliminary pixel defining layer may be less than a height of the spacer.

In an embodiment, the forming the pixel defining layer may include exposing and developing a portion of the preliminary pixel defining layer overlapping a portion of the anode electrode to form the pixel defining layer defining the opening.

In an embodiment, the display device may further include, after the forming of the pixel defining layer, forming a light-emitting layer disposed in the opening on the anode electrode.

In an embodiment, the light-emitting layer may be formed by an inkjet process.

In an embodiment, a distance from the substrate to an upper surface of the light-emitting layer may be less than a distance from the substrate to an upper surface of the spacer.

In an embodiment of the disclosure, an electronic device may include a processor, and a display device displaying an image in response to control of the processor, where the display device includes a plurality of sub-pixels, where sub-pixels emitting light of a same color among the plurality of sub-pixels are arranged in a same column, where each of the plurality of sub-pixels may include a substrate, an anode electrode disposed on the substrate, a spacer disposed in a same layer as the anode electrode, and a pixel defining layer defining an opening exposing the anode electrode and covering at least a part of the spacer on the spacer, and where a liquid repellency of the pixel defining layer is higher than a liquid repellency of the spacer.

### BRIEF DESCRIPTION OF THE DRAWINGS

The above and other features of embodiments of the disclosure will become more apparent by describing in further detailed embodiments thereof with reference to the accompanying drawings, in which:

FIG. 1 is a block diagram showing an embodiment of a display device.

FIG. 2 is a block diagram illustrating an embodiment of one of the sub-pixels of FIG. 1.

FIG. 3 is a plan view showing an embodiment of a display panel of FIG. 1.

FIG. 4 is a cross-sectional view showing an embodiment of the display panel of FIG. 3.

FIG. 5 is a cross-sectional view showing another embodiment of the display panel of FIG. 3.

FIG. 6 is an enlarged plan view of a part of a display area of the display panel of FIG. 3.

FIG. 7 is a cross-sectional view taken in line I-I’ of FIG. 6.

FIG. 8 is an enlarged cross-sectional view of an area A of FIG. 7.

FIG. 9 is a cross-sectional view illustrating another embodiment of FIG. 8.

FIGS. 10 to 16 are diagrams illustrating embodiments of a method of manufacturing a display device according to the disclosure.

FIG. 17 is a block diagram of an embodiment of an electronic device.

FIG. 18 shows schematic views of various embodiments of an electronic device.

### DETAILED DESCRIPTION

As the disclosure allows for various changes and numerous embodiments, particular embodiments will be illustrated in the drawings and described in detail in the written description. However, this is not necessarily intended to limit the disclosure to particular modes of practice, and it is to be appreciated that all changes, equivalents, and substitutes that do not depart from the spirit and technical scope of the disclosure are encompassed in the disclosure.

In describing the drawings, like reference numerals have been used for like elements. In the accompanying drawings, the dimensions of the structures are enlarged than the actual size in order to clearly explain the disclosure. It will be understood that, although the terms “first”, “second”, etc. may be used herein to describe various elements, these elements should not be limited by these terms. These terms are only used to distinguish one element from another element. For instance, a first element discussed below could be termed a second element without departing from the scope of the disclosure. Similarly, the second element could also be termed the first element.

It will be further understood that the terms “comprise”, “include”, “have”, etc. when used in the disclosure, specify the presence of stated features, integers, steps, operations, elements, components, and/or combinations of them but do not preclude the presence or addition of one or more other features, integers, steps, operations, elements, components, and/or combinations thereof. Furthermore, in case that a first part such as a layer, a film, a region, or a plate is disposed “on” a second part, the first part may be not only “directly on” the second part but a third part may intervene between them. In addition, when it is expressed that a first part such as a layer, a film, a region, or a plate is formed on a second part, the surface of the second part on which the first part is formed is not necessarily limited to an upper surface of the second part but may include other surfaces such as a side surface or a lower surface of the second part. To the contrary, in case that a first part such as a layer, a film, a region, or a plate is “under” a second part, the first part may be not only “directly under” the second part but a third part may intervene between them.

Hereinafter, embodiments of the disclosure will be described in detail with reference to the accompanying drawings. In the disclosure, the singular forms are intended to include the plural forms as well, unless the context clearly indicates otherwise.

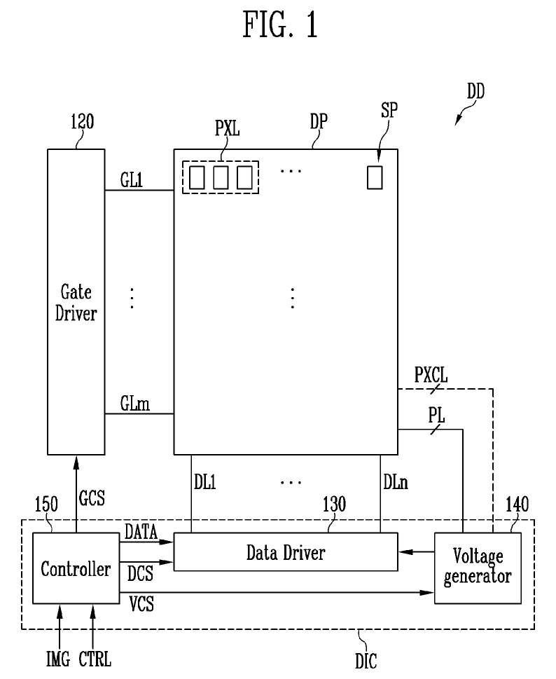

FIG. 1 is a block diagram showing an embodiment of a display device DD.

Referring to FIG. 1, the display device DD may include a display panel DP, a gate driver 120, a data driver 130, a voltage generator 140, and a controller 150.

The display panel DP includes sub-pixels SP. The sub-pixels SP may be connected to the gate driver 120 through first to m-th gate lines GL1 to GLm where m is a natural number. The sub-pixels SP may be connected to the data driver 130 through first to n-th data lines DL1 to DLn where n is a natural number.

The sub-pixels SP may generate light of two or more colors. In an embodiment, each of the sub-pixels SP may generate light of a color such as red, green, blue, cyan, magenta, or yellow, for example.

Two or more sub-pixels of the sub-pixels SP may constitute one pixel PXL. In an embodiment, the pixel PXL may include three sub-pixels as shown in FIG. 1, for example. As such, the pixel PXL may emit light of various colors and various luminances depending on the combination of light emitted from the sub-pixels included therein.

The gate driver 120 is connected to the sub-pixels SP arranged in a row direction through the first to m-th gate lines GL1 to GLm. The gate driver 120 may output gate signals to the first to m-th gate lines GL1 to GLm in response to a gate control signal GCS. In an embodiment, the gate control signal GCS may include a start signal indicating the start of each frame, a horizontal synchronization signal, or the like.

The gate driver 120 may be disposed on one side of the display panel DP. However, the disclosure is not limited thereto. In an embodiment, the gate driver 120 may be divided into two or more drivers which are physically and/or logically divided, and these drivers may be disposed on one side of the display panel DP and an opposite side of the display panel DP opposite to the one side, for example. As such, the gate driver 120 may be disposed around the display panel DP in various forms.

The data driver 130 is connected to the sub-pixels SP arranged in a column direction through the first to n-th data lines DL1 to DLn. The data driver 130 receives image data DATA and a data control signal DCS from the controller 150. The data driver 130 operates in response to the data control signal DCS. In an embodiment, the data control signal DCS may include a source start signal, a source shift clock, a source output enable signal, etc.

The data driver 130 may receive voltages from the voltage generator 140. The data driver 130 may apply data signals having grayscale voltages corresponding to the image data DATA to the first to n-th data lines DL1 to DLn by the received voltages. When the gate signals are applied to the first to m-th gate lines GL1 to GLm, data signals corresponding to the image data DATA may be applied to the first to n-th data lines DL1 to DLn. Accordingly, the sub-pixels SP may generate light corresponding to the data signals, and the display panel DP may display an image.

In an embodiment, the gate driver 120 and the data driver 130 may include complementary metal-oxide semiconductor (“CMOS”) circuit elements.

The voltage generator 140 may operate in response to a voltage control signal VCS from the controller 150. The voltage generator 140 generates a plurality of voltages and provide the generated voltages to components of the display device DD, such as the gate driver 120, the data driver 130, and the controller 150. The voltage generator 140 may receive an input voltage from the outside of the display device DD and regulate the received voltage to thereby generate a plurality of voltages.

The voltage generator 140 may generate a first power supply voltage and a second power supply voltage. The generated first and second power supply voltages may be provided to the sub-pixels SP via power lines PL. In other embodiments, at least one of the first and second power supply voltages may be provided from the outside of the display device DD.

In addition, the voltage generator 140 may provide various voltages and/or signals. In an embodiment, the voltage generator 140 may provide one or more initialization voltages applied to the sub-pixels SP, for example. In an embodiment, during a sensing operation of sensing electrical characteristics of transistors and/or light-emitting elements of the sub-pixels SP, a predetermined reference voltage may be applied to the first to n-th data lines DL1 to DLn, and the voltage generator 140 may generate and transmit the reference voltage to the data driver 130, for example. In an embodiment, during a display operation of displaying an image on the display panel DP, common pixel control signals may be applied to the sub-pixels SP, and the voltage generator 140 may generate the pixel control signals, for example. In an embodiment, the voltage generator 140 may provide the pixel control signals to the sub-pixels SP through pixel control lines PXCL. Although the pixel control lines PXCL are shown in FIG. 1 as being connected between the voltage generator 140 and the display panel DP, the disclosure is not limited thereto. In an embodiment, the pixel control lines PXCL may be connected between the gate driver 120 and the display panel DP, for example. The pixel control signals may be transferred from the voltage generator 140 to the pixel control lines PXCL through the gate driver 120.

The controller 150 controls various operations of the display device DD. The controller 150 receives the input image data IMG and the corresponding control signal CTRL from the outside. The controller 150 may provide the gate control signal GCS, the data control signal DCS, and the voltage control signal VCS in response to the control signal CTRL.

The controller 150 may output the image data DATA by converting the input image data IMG to be suitable for the display device DD or the display panel DP. In an embodiment, the controller 150 may output the image data DATA by aligning the input image data IMG to fit the sub-pixels SP in rows.

Two or more components among the data driver 130, the voltage generator 140, and the controller 150 may be disposed (e.g., mounted) in one integrated circuit. As shown in FIG. 1, the data driver 130, the voltage generator 140, and the controller 150 may be included in a driver integrated circuit DIC. The data driver 130, the voltage generator 140, and the controller 150 may be functionally distinct components within one driver integrated circuit DIC. In other embodiments, at least one of the data driver 130, the voltage generator 140, and the controller 150 may be provided as a component separate from the driver integrated circuit DIC.

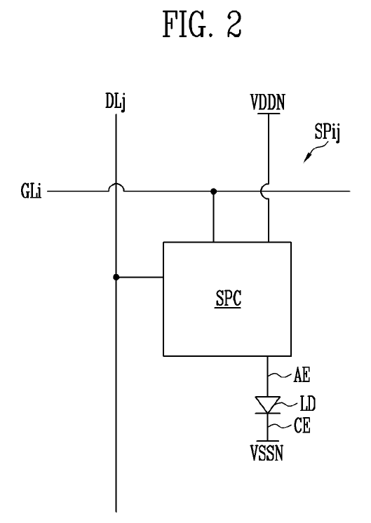

FIG. 2 is a block diagram illustrating an embodiment of one of the sub-pixels SP of FIG. 1. In FIG. 2, among the sub-pixels SP in FIG. 1, a sub-pixel SPij disposed in an i-th row (i is an integer greater than or equal to 1 and less than or equal to m) and a j-th column (j is an integer greater or equal to 1 and less than or equal to n) is shown.

Referring to FIG. 2, the sub-pixel SPij may include a sub-pixel circuit SPC and a light-emitting element LD.

The light-emitting element LD is connected between a first power supply voltage node VDDN and a second power supply voltage node VSSN. The first power supply voltage node VDDN is connected to one of the power lines (also referred to as power supply lines) PL in FIG. 1 and receives the first power supply voltage. The second power supply voltage node VSSN is connected to another power supply line PL in FIG. 1 and receives the second power supply voltage. The first power supply voltage may have a higher voltage level than the second power supply voltage.

The light-emitting element LD is connected between an anode electrode AE and a cathode electrode CE. The anode electrode AE may be connected to the first power supply voltage node VDDN the sub-pixel circuit SPC. In an embodiment, the anode electrode AE may be connected to the first power supply voltage node VDDN through one or more transistors included in the sub-pixel circuit SPC, for example. The cathode electrode CE may be connected to the second power supply voltage node VSSN. The light-emitting element LD emits light according to a current flowing from the anode electrode AE to the cathode electrode CE.

The sub-pixel circuit SPC may be connected to an i-th gate line GLi among the first to m-th gate lines GL1 to GLm of FIG. 1, and a j-th data line DLj among the first to n-th data lines DL1 to DLn of FIG. 1. In response to the gate signal received via the i-th gate line GLi, the sub-pixel circuit SPC controls the light-emitting element LD to emit light in accordance with the data signal received via the j-th data line DLj. In an embodiment, the sub-pixel circuit SPC may be further connected to the pixel control lines PXCL of FIG. 1. The sub-pixel circuit SPC may control the light-emitting element LD further in response to pixel control signals received via the pixel control lines PXCL.

For such operations, the sub-pixel circuit SPC may include circuit elements, e.g., transistors and one or more capacitors.

The transistors of the sub-pixel circuit SPC may include P-type transistors and/or N-type transistors. In an embodiment, the transistors of the sub-pixel circuit SPC may include a Metal Oxide Silicon Field Effect Transistor (“MOSFET”). In an embodiment, the transistors of the sub-pixel circuit SPC may include an amorphous silicon semiconductor, a monocrystalline silicon, a polycrystalline silicon semiconductor, an oxide semiconductor, or the like.

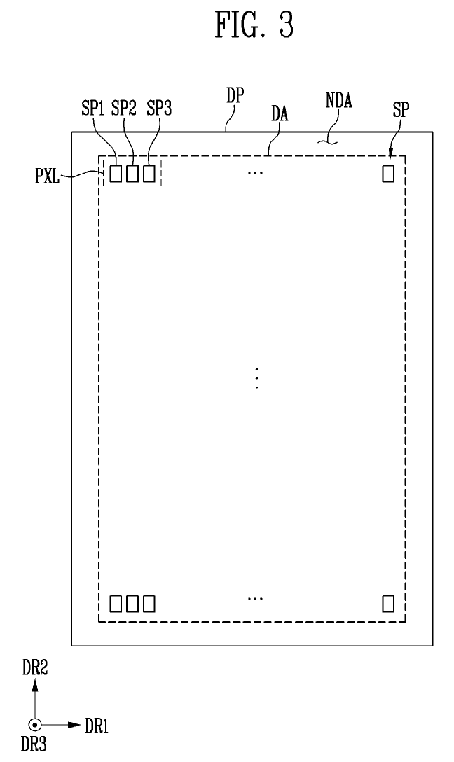

FIG. 3 is a plan view showing an embodiment of the display panel DP of FIG. 1.

Referring to FIG. 3, the display panel DP may include a display area DA and a non-display area NDA. The display panel DP displays an image through the display area DA. The non-display area NDA is disposed around the display area DA.

The display panel DP includes the sub-pixels SP in the display area DA. The sub-pixels SP may be arranged in a first direction DR1 and a second direction DR2 intersecting the first direction DR1. In an embodiment, the sub-pixels SP may be arranged in a matrix format in the first direction DR1 and the second direction DR2, for example. In another embodiment, the sub-pixels SP may be arranged in a zigzag pattern in the first direction DR1 and the second direction DR2. The arrangement of the sub-pixels SP may vary in other embodiments. The first direction DR1 may be a row direction and the second direction DR2 may be a column direction.

Two or more sub-pixels of the plurality of sub-pixels SP may constitute one pixel PXL. In FIG. 3, the pixel PXL is shown as including three sub-pixels (SP1 to SP3), but the disclosure is not limited thereto. In an embodiment, the pixel PXL may include two sub-pixels, for example. Hereinafter, for convenience of description, it is assumed that the pixel PXL includes first, second, and third sub-pixels SP1, SP2, and SP3.

Each of the first to third sub-pixels SP1 to SP3 may generate light of one of various colors such as red, green, blue, cyan, magenta, yellow, or the like. Hereinafter, for clear and concise description, it is assumed that the first sub-pixel SP1 generates light of a red color, the second sub-pixel SP2 generates the light of a green color, and the third sub-pixel SP3 generates the light of a blue color.

Each of the first to third sub-pixels SP1 to SP3 may include at least one light-emitting element which generates light. In an embodiment, the light-emitting elements of the first to third sub-pixels SP1 to SP3 may generate light of the same color. In an embodiment, the light-emitting elements of the first to third sub-pixels SP1 to SP3 may generate blue-colored light, for example. In other embodiments, the light-emitting elements of the first to third sub-pixels SP1 to SP3 may generate light of different colors from each other. In an embodiment, the light-emitting elements of the first to third sub-pixels SP1 to SP3 may generate light of a red color, a green color, and a blue color, respectively, for example.

As the display panel DP, a self-luminous display panel such as a light-emitting diode (“LED”) display panel using a micro-scale or nano-scale light-emitting diode as a light-emitting element, an organic light-emitting display (“OLED”) panel using an organic light-emitting diode as a light-emitting element, or the like may be used.

In the non-display area NDA, a component for controlling the sub-pixels SP may be disposed. Wirings connected to the sub-pixels SP, e.g., the first to m-th gate lines GL1 to GLm, the first to n-th data lines DL1 to DLn, the power lines PL, and the pixel control lines PXCL of FIG. 1 may be arranged in the non-display area NDA.

At least one of the gate driver 120, the data driver 130, the voltage generator 140, and the controller 150 of FIG. 1 may be disposed in the non-display area NDA of the display panel DP. In an embodiment, the gate driver 120 may be disposed in the non-display area NDA. The data driver 130, the voltage generator 140, and the controller 150 may be implemented in the driver integrated circuit DIC of FIG. 1 which is separate from the display panel DP. The driver integrated circuit DIC may be connected to wirings arranged in the non-display area NDA. In other embodiments, the gate driver 120 may be implemented together with the data driver 130, the voltage generator 140, and the controller 150 in one integrated circuit which is separate from the display panel DP.

In an embodiment, the display area DA may have various shapes. The display area DA may have a shape of a closed loop including straight and/or curved sides. In an embodiment, the display area DA may have shapes such as a polygon, a circle, a semicircle, an ellipse, etc., for example.

In an embodiment, the display panel DP may have a flat display surface. In other embodiments, the display panel DP may have an at least partially round display surface. In an embodiment, the display panel DP may be bendable, foldable, or rollable. In such embodiments, a substrate of the display panel DP and/or the display panel DP may include materials having a flexible property.

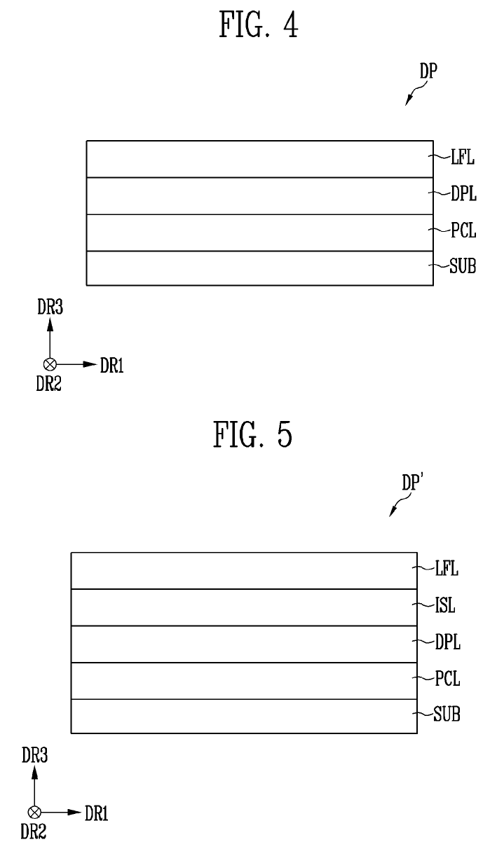

FIG. 4 is a cross-sectional view showing an embodiment of the display panel DP of FIG. 3.

Referring to FIG. 4, the display panel DP may include a substrate SUB, a pixel circuit layer PCL, a display element layer DPL, and a light functional layer LFL sequentially stacked in a third direction DR3 (e.g., a thickness direction of the substrate SUB) intersecting the first and second directions DR1 and DR2 on the substrate SUB.

The substrate SUB may include an insulating material such as glass, or resin. In an embodiment, the substrate SUB may include a glass substrate, for example. In another embodiment, the substrate SUB may include a polyimide (“PI”) substrate. In another embodiment, the substrate SUB may include a silicon wafer substrate manufactured using semiconductor processes.

In an embodiment, the substrate SUB may include a material which is flexible to allow bending or folding, and may have a single-layer structure or a multi-layer structure. In an embodiment, the flexible material may include at least one of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and cellulose acetate propionate, for example. However, the disclosure is not limited thereto.

The pixel circuit layer PCL is disposed on the substrate SUB. The pixel circuit layer PCL may include insulating layers and semiconductor patterns and conductive patterns arranged between the insulating layers. The conductive patterns of the pixel circuit layer PCL may function as circuit elements, wirings, or the like.

The circuit elements of the pixel circuit layer PCL may include the sub-pixel circuit SPC in FIG. 2 of each of the sub-pixels SP of FIG. 3. In other words, the circuit elements of the pixel circuit layer PCL may be provided with transistors and one or more capacitors of the sub-pixel circuit SPC.

The wirings of the pixel circuit layer PCL may include wirings connected to the sub-pixels SP. Wirings of the pixel circuit layer PCL may include various signal lines and/or voltage lines desired for driving the display element layer DPL.

The display element layer DPL is disposed on the pixel circuit layer PCL. The display element layer DPL may include light-emitting elements of the sub-pixels SP.

The light functional layer LFL may be disposed on the display element layer DPL. The light functional layer LFL may include light conversion patterns with color conversion particles and/or scattering particles. In an embodiment, the color conversion particles may include quantum dots, for example. The quantum dots may change the wavelength (or color) of light emitted from the display element layer DPL. The light functional layer LFL may further include light scattering patterns with scattering particles. In an embodiment, light converting patterns and light scattering patterns may be omitted.

The light functional layer LFL may further include a color filter layer including color filters. The color filters may selectively transmit light of a predetermined wavelength (or a predetermined color). In an embodiment, the color filter layer may be omitted.

A window for protecting an exposed surface (or an upper surface) of the display panel DP may be provided on the light functional layer LFL. The window may protect the display panel DP from external impact. The window may be coupled to the light functional layer LFL through an optically clear adhesive (or bonding) member. The window may have a multilayer structure selected from a glass substrate, a plastic film, and a plastic substrate. Such a multilayer structure may be formed through a continuous process or an adhesive process using an adhesive layer. The whole or a part of the window may be flexible.

FIG. 5 is a cross-sectional view showing another embodiment of the display panel DP of FIG. 3.

Referring to FIG. 5, a display panel DP′ may include the substrate SUB, the pixel circuit layer PCL, the display element layer DPL, an input sensing layer ISL, and the light functional layer LFL. The substrate SUB, the pixel circuit layer PCL, the display element layer DPL, and the light functional layer LFL are configured in a similar manner to the substrate SUB, the pixel circuit layer PCL, the display element layers DPL, and light functional layer LFL, respectively, as described with reference to FIG. 4. Hereinafter, duplicate explanations are omitted.

The input sensing layer ISL may sense a user input to a top surface (or a display surface) of the display panel DP′. The input sensing layer ISL may include configurations suitable for sensing external objects such as a user’s hand, a pen, etc. In an embodiment, the input sensing layer ISL may include touch electrodes, for example.

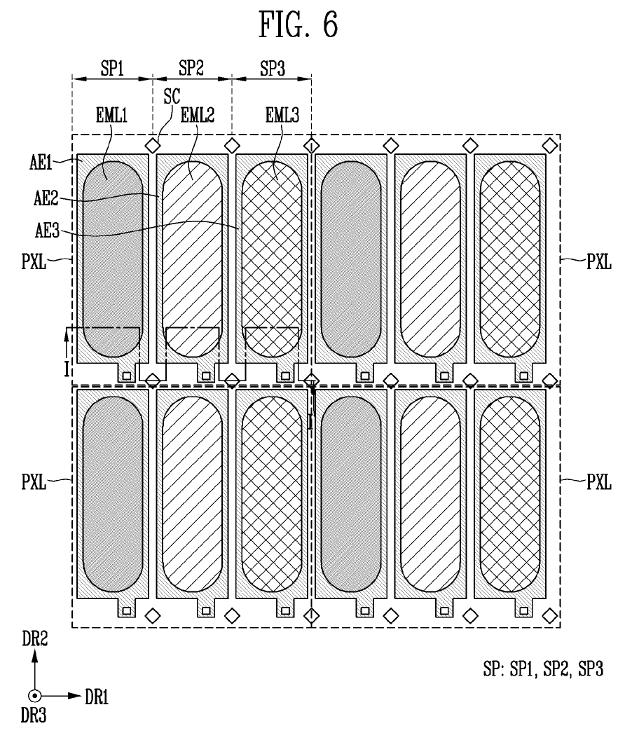

FIG. 6 is an enlarged plan view of a part of the display area DA of the display panel DP of FIG. 3.

Referring to FIG. 6, the display panel DP may include the plurality of pixels PXL in the display area DA. The plurality of pixels PXL may include first to fourth pixels PXL1 to PXL4 which are arranged in the first direction DR1 and the second direction DR2.

Each of the plurality of pixels PXL includes the sub-pixels SP. The plurality of sub-pixels SP included in one pixel PXL may each emit light of different colors. In an embodiment, the sub-pixels SP which are included in one pixel PXL and emit light of different colors may be arranged in the first direction DR1. In an embodiment, among the plurality of sub-pixels SP which are included in neighboring (adjacent) pixels PXL, the sub-pixels SP which emit light of the same color may be arranged in the same column (e.g., in the second direction DR2). That is, the plurality of sub-pixels SP may be arranged in a stripe format. However, the disclosure is not limited thereto.

The sub-pixels SP may include the first to third sub-pixels SP1 to SP3. Each of the first to third sub-pixels SP1 to SP3 may include a portion of a display device disposed in a corresponding region. In an embodiment, the first to third sub-pixels SP1 to SP3 may include first to third anode electrodes AE1 to AE3 and first to third light-emitting layers EML1 to EML3, respectively, for example. The first to third light-emitting layers EML1 to EML3 may be arranged on the first to third anode electrodes AE1 to AE3, respectively. The first light-emitting layer EML1 may generate light of a red color, the second light-emitting layer EML2 may generate light of a green color, and the third light-emitting layer EML3 may generate light of a blue color. However, the disclosure is not limited thereto.

The first to third anode electrodes AE1 to AE3 may be spaced apart from each other. The first to third light-emitting layers EML1 to EML3 may also be spaced apart from one another. The first to third light-emitting layers EML1 to EML3 may be formed separately by an inkjet process and may not extend entirely on the first to third sub-pixels SP1 to SP3.

Spacers SC may be arranged at a boundary between the first to third sub-pixels SP1 to SP3, respectively. The spacers SC may be arranged between the first to third anode electrodes AE1 to AE3, respectively, and may protrude from the substrate SUB. The spacing between the display element layer DPL and a component disposed on top of the display element layer DPL (e.g., the light functional layer LFL of FIG. 4 or the input sensing layer ISL of FIG. 5) may be kept constant through the spacers SC.

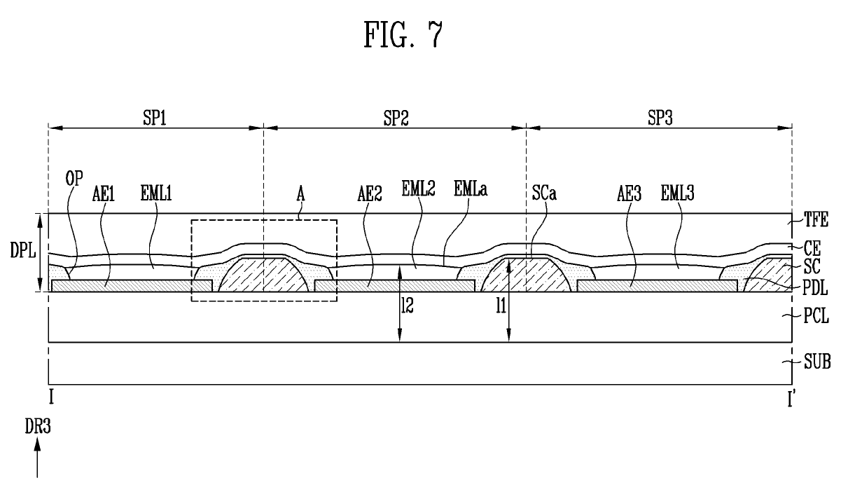

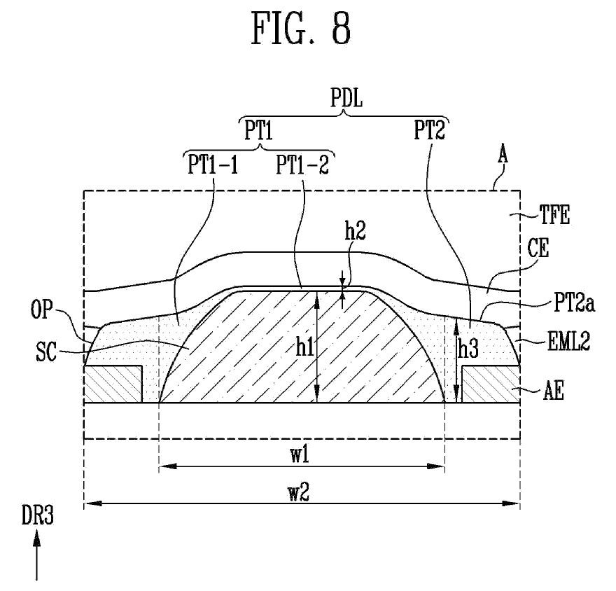

FIG. 7 is a cross-sectional view taken in line I-I’ of FIG. 6. In an embodiment, FIG. 7 is a cross-sectional view showing only the pixel circuit layer PCL and the display element layer DPL of the display panel DP, for example. FIG. 8 is an enlarged cross-sectional view of the area A of FIG. 7.

Referring to FIG. 7, the display element layer DPL may be disposed on the substrate SUB and the pixel circuit layer PCL. The display element layer DPL may include the first to third anode electrodes AE1 to AE3, the spacer SC, a pixel defining layer PDL, the first to third light-emitting layers EML1 to EML3, the cathode electrode CE, and an encapsulation layer TFE.

Specifically, the first to third anode electrodes AE1 to AE3 may be arranged on the pixel circuit layer PCL. The first to third anode electrodes AE1 to AE3 may be spaced apart from each other and overlap the first to third sub-pixels SP1 to SP3, respectively.

The spacers SC may be respectively arranged between the first to third anode electrodes AE1 to AE3 on the pixel circuit layer PCL. The spacers SC may be arranged in the same layers as the first to third anode electrodes AE1 to AE3. In an embodiment, the spacers SC may not overlap the first to third anode electrodes AE1 to AE3. However, the disclosure is not limited thereto.

The spacers SC may be disposed to protrude from the first to third light-emitting layers EML1 to EML3 in order to maintain a constant distance between the display panel DP and other components including an encapsulation substrate disposed on the encapsulation layer TFE. Therefore, a distance l1 from the substrate SUB to an upper surface SCa of the spacer SC may be greater than a distance l2 from the substrate SUB to an upper surface EMLa of each of the first to third light-emitting layers EML1 to EML3.

Each of the spacers SC may include an organic material. In an embodiment, each of the spacers SC may include at least one of a polyimide-based resin and an acrylate-based resin, for example.

The pixel defining layer PDL may be disposed on the pixel circuit layer PCL and the spacers SC. The pixel defining layer PDL may cover an edge of each of the first to third anode electrodes AE1 to AE3, and may cover at least a part of the spacer SC.

The pixel defining layer PDL may include an organic material. In an embodiment, the pixel defining layer PDL may include at least one of a polyimide-based resin and an acrylate-based resin, for example.

In an embodiment, at least a part of a surface of the pixel defining layer PDL covering the spacer SC may have liquid repellency. Liquid repellency may refer to a property that a surface of an object does not have an affinity for a liquid, causing the liquid not to be absorbed by the object but instead to form droplets or easily flow off the surface of the object. The degree of liquid repellency may be measured based on the contact angle defined by the liquid droplet with the surface. In an embodiment, when a liquid droplet has a contact angle greater than about 90 degrees with a surface of an object, the object may be described as having liquid repellency, for example. However, the disclosure is not limited thereto. In addition, when an object has higher liquid repellency than another object, it may mean that a contact angle between a liquid droplet and a surface of the object is greater than a contact angle between the liquid droplet and a surface of another object. Conversely, when an object has lower liquid repellency than another object, it may mean that a contact angle between a liquid droplet and a surface of one object is smaller than a contact angle between the liquid droplet and a surface of another object.

In an embodiment, the pixel defining layer PDL may further include fluorine (F) in an organic material, for example. At least a part of the surface of the pixel defining layer PDL may have liquid repellency because the pixel defining layer PDL further includes or consists of fluorine in the organic material. Accordingly, the pixel defining layer PDL includes a material different from the spacer SC, and the liquid repellency of the pixel defining layer PDL may be higher than that of the spacer SC. The spacer SC may be in overall contact with the pixel defining layer PDL. That is, no other layers may be interposed between the spacer SC and the pixel defining layer PDL. Therefore, the entirety of the surface of the spacer SC other than the bottom surface of the spacer SC which contacts the pixel circuit layer PCL may contact the pixel defining layer PDL.

Referring further to FIG. 8, the pixel defining layer PDL may have a larger width than the spacer SC. Since a width w2 of the pixel defining layer PDL is larger than a width w1 of the spacer SC, the pixel defining layer PDL may surround a side surface of the spacer SC and edges of the first to third anode electrodes AE1 to AE3.

The pixel defining layer PDL may include a first portion PT1 and a second portion PT2.

The first portion PT1 may be a part of the pixel defining layer PDL which overlaps the spacer SC in a plan view. The second portion PT2 may be formed integrally with the first portion PT1, and may have a height smaller than that of the spacer SC.

The first portion PT1 may cover at least a part of the spacer SC and have a shape which flows down along a part of an upper surface and the side surface of the spacer SC. That is, a height h2 of the first portion PT1 may be generally less than or equal to the maximum height of the second portion PT2. In addition, a part of the first portion PT1 on the upper surface of the spacer SC may be in the form of a thin film or may be discontinuously arranged.

The second portion PT2 may surround the first portion PT1 and be formed integrally with the first portion PT1. That is, the second portion PT2 may include the same material as that of the first portion PT1. The second portion PT2 may cover an edge of each of the first to third anode electrodes AE1 to AE3 on the pixel circuit layer PCL. A height h3 of the second portion PT2 may be generally smaller than a height h1 of the spacer SC. That is, a distance from the substrate SUB to the upper surface of the spacer SC may be greater than the distance from the substrate SUB to an upper surface of the second portion PT2. Thus, the spacer SC may have a structure which protrudes in the third direction DR3 above from the top surface of the second portion PT2. The first portion PT1 may cover at least a part of the surface of the spacer SC which protrudes above from the top surface the second portion PT2.

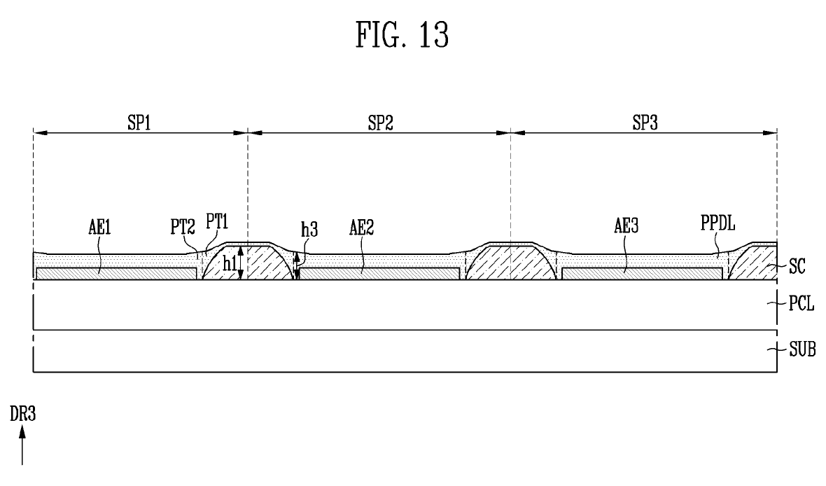

More specifically, the first portion PT1 may include a (1-1)th portion PT1-1 disposed on the side surface of the spacer SC and a (1-2)th portion PT1-2 disposed on the upper surface of the spacer SC. A height of the (1-2)th portion PT1-2 in the height h2 of the first portion PT1 may be less than or equal to a height of the (1-1)th portion PT1-1. Since the pixel defining layer PDL is entirely applied on the spacer SC, and the pixel defining layer PDL disposed on the upper surface of the spacer SC flows down along the side surface of the spacer SC, the (1-2)th portion PT1-2 disposed on the upper surface of the spacer SC may be formed thinner than the (1-1)th portion PT1-1 (refer to FIG. 13).

In an embodiment, an upper surface PT2a and the side surface of the second portion PT2 extending from the first portion PT1 includes fluorine, so that the upper surface PT2a and the side surface of the second portion PT2 extending from the first portion PT1 may have liquid repellency. Accordingly, when the first to third light-emitting layers EML1 to EML3 are formed by an inkjet process, color mixing between the first to third light-emitting layers EML1 to EML3 may be prevented by the surface of the pixel defining layer PDL having the liquid repellency.

The pixel defining layer PDL may define openings OP exposing the first to third anode electrodes AE1 to AE3, respectively. The first to third light-emitting layers EML1 to EML3 may be respectively arranged on the first to third anode electrodes AE1 to AE3 in the openings OP. The first to third light-emitting layers EML1 to EML3 may be individually formed by an inkjet process. Accordingly, the first to third light-emitting layers EML1 to EML3 may be spaced apart without being connected to each other.

The cathode electrode CE may be entirely disposed on the first to third light-emitting layers EML1 to EML3, the spacer SC, and the pixel defining layer PDL. The cathode electrode CE may extend entirely on the first to third sub-pixels SP1 to SP3. The encapsulation layer TFE may be disposed on the cathode electrode CE. The encapsulation layer TFE may protect the underlying components.

In an embodiment, the liquid-repellent pixel defining layer PDL covers the spacer SC, so that the first to third light-emitting layers EML1 to EML3 may be prevented from crossing over the pixel defining layer PDL to neighboring sub-pixels to cause color mixing. In addition, a portion (e.g., the second portion PT2) of the pixel defining layer PDL which does not overlap the spacer SC has a height less than that of the spacer SC, so that the first portion PT1 of the pixel defining layer PDL may protrude from the second portion PT2 to serve as the spacer SC. A separate structure or a separate process is not added therefor, so it is possible to improve the reliability of the display device by preventing color mixing and at the same time, to simplify the structure of the display device and improve manufacturing efficiency thereof.

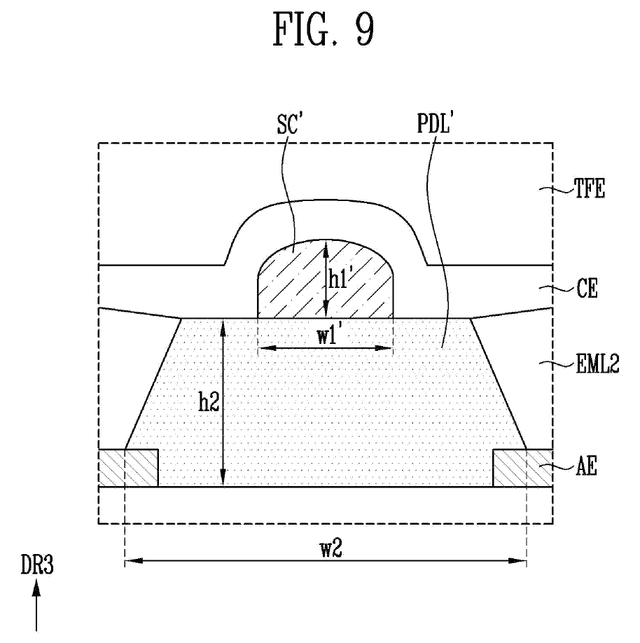

FIG. 9 is a cross-sectional view illustrating another embodiment of FIG. 8. The embodiment according to FIG. 9 may be substantially identical to the embodiment according to FIG. 8, with the exception of a pixel defining layer PDL′ and a spacer SC′. Accordingly, redundant explanations will be omitted.

Referring to FIG. 9, the pixel defining layer PDL′ may be disposed on the substrate SUB. The spacer SC′ may be disposed on the pixel defining layer PDL′. The spacer SC′ may have a smaller width w1′ and a smaller height h1′ than the pixel defining layer PDL′. That is, the width w1’ and the height h1′ of the spacer SC′ may be smaller than the width w2 and the height h2 of the pixel defining layer PDL′. Accordingly, the spacer SC′ may not cover the entirety of the surface of the pixel defining layer PDL′, and may be disposed only on an upper surface of the pixel defining layer PDL′.

At least a part of the surface of each of the pixel defining layer PDL′ and the spacer SC′ may have liquid repellency. In an embodiment, each of the pixel defining layer PDL′ and the spacer SC′ includes an organic material, and at least a part of a surface of each of the pixel defining layer PDL′ or the spacer SC’ may further include fluorine, for example. That is, since each of the pixel defining layer PDL′ and the spacer SC′ includes or consists of fluorine, at least a part of the surfaces of the pixel defining layer PDL′ and the spacer SC′ may have liquid repellency.

The spacer SC′ disposed on the pixel defining layer PDL′ may be formed by an inkjet process. Since the surface of the pixel defining layer PDL′ has liquid repellency, the spacer SC′ formed by the inkjet process may not flow down on the pixel defining layer PDL′. In addition, since the spacer SC′ is formed by an inkjet process rather than a photolithography process, the fluorine on the surface of the pixel defining layer PDL′ may not be removed during the process of manufacturing the spacer SC. Accordingly, since the liquid repellency of the surface of each of the pixel defining layer PDL′ and the spacer SC′ is maintained, color mixing may be prevented when the light-emitting layer is formed.

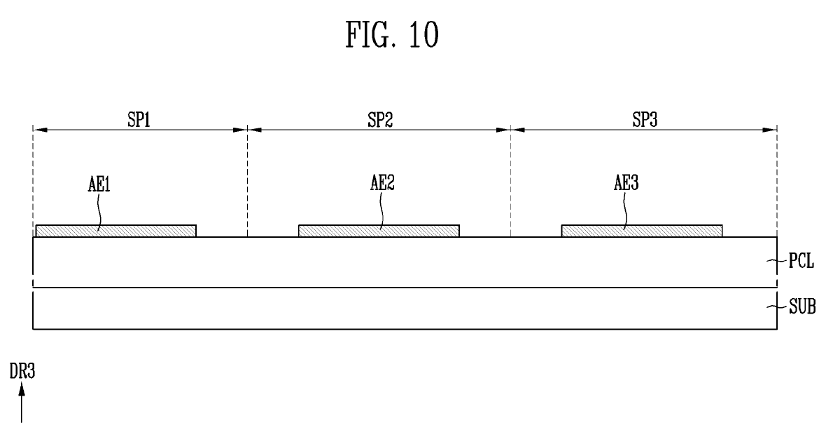

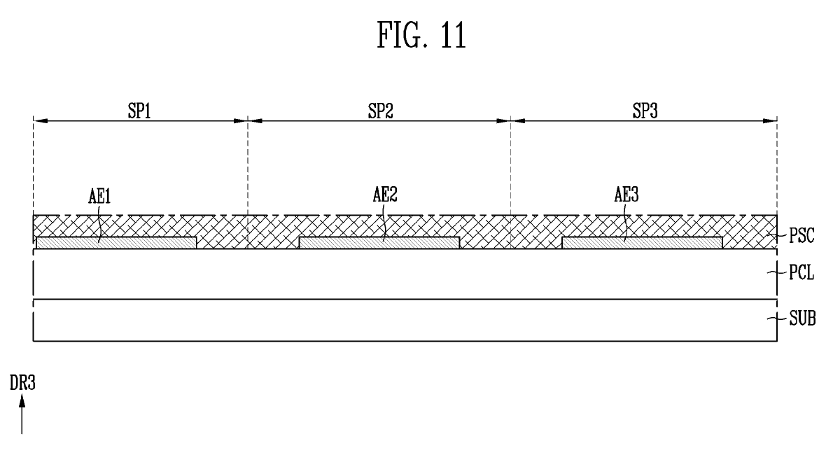

FIGS. 10 to 16 are diagrams illustrating embodiments of a method of manufacturing a display device according to the disclosure. In an embodiment, FIGS. 10 to 16 illustrate a method of manufacturing a display device in the embodiment of FIGS. 7 and 8, for example.

Referring to FIG. 10, the pixel circuit layer PCL may be formed on the substrate SUB. The first to third anode electrodes AE1 to AE3 may be formed on the pixel circuit layer PCL. The first to third anode electrodes AE1 to AE3 may be spaced apart from each other and overlap the first to third sub-pixels SP1 to SP3, respectively.

Referring to FIG. 11, a preliminary spacer PSC may be entirely applied on the pixel circuit layer PCL and the first to third anode electrodes AE1 to AE3. The preliminary spacer PSC may include an organic material. In an embodiment, the preliminary spacer PSC may include at least one of a polyimide-based resin and an acrylate-based resin, for example.

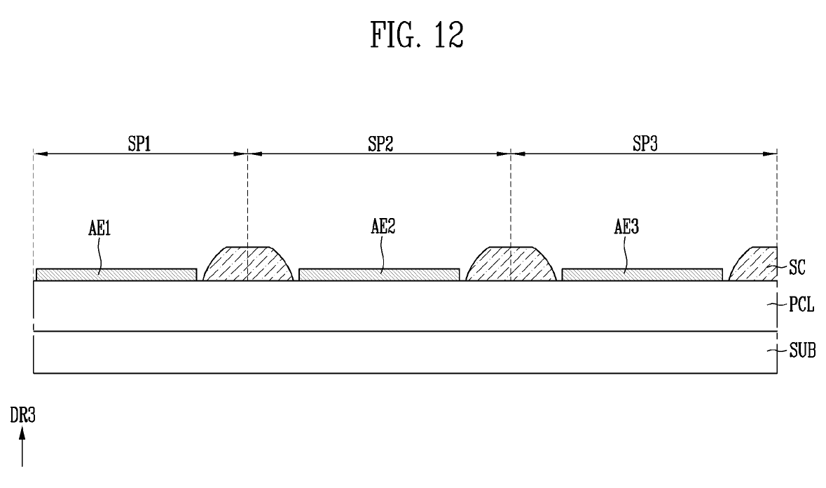

Referring to FIG. 12, the spacers SC may be formed by exposing and developing a portion of the preliminary spacer PSC. The spacers SC may be formed in the same layer as the first to third anode electrodes AE1 to AE3. In an embodiment, the spacers SC may be formed between the first to third anode electrodes AE1 to AE3, respectively, without overlapping the first to third anode electrodes AE1 to AE3. However, the disclosure is not limited thereto.

Referring to FIG. 13, a preliminary pixel defining layer PPDL may be entirely formed on the pixel circuit layer PCL, the first to third anode electrodes AE1 to AE3, and the spacers SC. The preliminary pixel defining layer PPDL may include a material having liquid repellency. In an embodiment, the preliminary pixel defining layer PPDL may include a material in which a fluorine additive including fluorine is mixed with an organic material, for example. However, the disclosure is not limited thereto, and In another embodiment, after the preliminary pixel defining layer PPDL includes an organic material, fluorine may be added to the surface of the preliminary pixel defining layer PPDL by surface treatment through plasma treatment using fluorine gas to ensure liquid repellency.

The height h3 of the preliminary pixel defining layer PPDL may be smaller than the height h1 of the spacer SC. In addition, the height from an upper surface of the preliminary pixel defining layer PPDL which does not overlap the spacer SC to the substrate SUB may be greater than the height from the upper surface of the spacer SC to the substrate SUB. By applying the preliminary pixel defining layer PPDL to the height h3 smaller than the height h1 of the spacer SC, a structure in which the spacer SC protrudes from the preliminary pixel defining layer PPDL may be formed. The spacer SC may thus serve to keep a constant distance between the components arranged on top of the spacer SC.

Since the preliminary pixel defining layer PPDL is applied on the spacer SC, the material forming the preliminary pixel defining layer PPDL may partially remain on the surface of the spacer SC protruding from the preliminary pixel defining layer PPDL. The preliminary pixel defining layer PPDL may include the first portion PT1 overlapping the spacer SC in a plan view and the second portion PT2 formed integrally with the first portion PT1 and having a height less than the spacer SC and greater than or equal to that of the first portion PT1. That is, the second portion PT2 is formed on the pixel circuit layer PCL at the height h3 less than that of the spacer SC, and the first portion PT1 may remain on the surface of the spacer SC protruding from the preliminary pixel defining layer PPDL.

The first portion PT1 and the second portion PT2 may be formed integrally and simultaneously with the same material as each other.

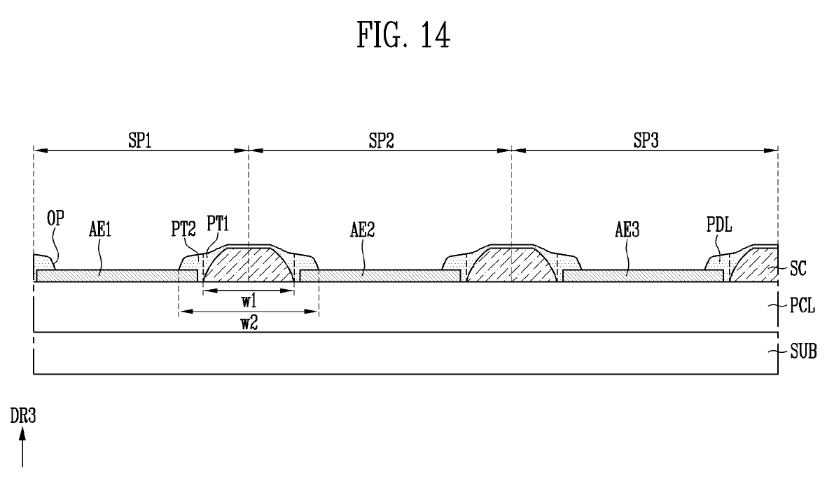

Referring to FIG. 14, the preliminary pixel defining layer PPDL may be partially removed through a photolithography process to form the pixel defining layer PDL. The pixel defining layer PDL defining the opening OP which exposes each of the first to third anode electrodes AE1 to AE3 may be formed by exposing and developing a portion of the preliminary pixel defining layer PPDL which overlaps with a portion of each of the first to third anode electrodes AE1 to AE3. Specifically, by exposing and developing a part of the second portion PT2 of the preliminary pixel defining layer PPDL, the pixel defining layer PDL defining the openings OP may be formed. The openings OP may be defined in the first to third sub-pixels SP1 to SP3, may overlap the first to third anode electrodes AE1 to AE3, and may expose the first to third anode electrodes AE1 to AE3, respectively.

The width w2 of the pixel defining layer PDL covering the spacer SC may be larger than the width w1 of the spacer SC. Accordingly, the pixel defining layer PDL may cover the edge of each of the first to third anode electrodes AE1 to AE3, and the surface of the spacer SC is covered by the pixel defining layer PDL, so that the liquid repellency of the display area DA in which the pixel defining layer PDL is disposed may be maintained.

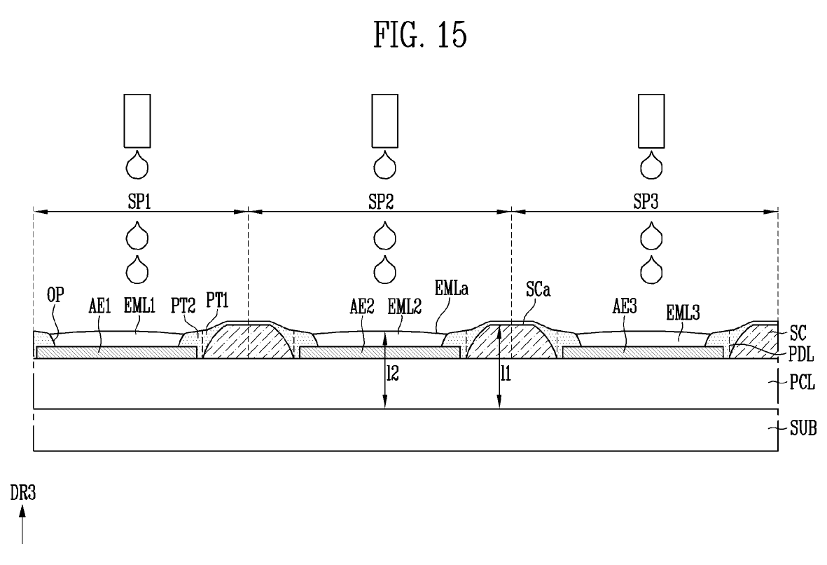

Referring to FIG. 15, the first to third light-emitting layers EML1 to EML3 may be respectively formed in the openings OP on the first to third anode electrodes AE1 to AE3, respectively. The first to third light-emitting layers EML1 to EML3 may be formed by an inkjet process. Inks constituting the first to third light-emitting layers EML1 to EML3 may be prevented from being mixed with each other by the liquid repellency of the surface of the pixel defining layer PDL.

The spacer SC may protrude beyond the first to third light-emitting layers EML1 to EML3 in order to maintain a constant distance between the display panel DP and other components including the encapsulation substrate disposed on the encapsulation layer TFE. That is, the distance l2 from the substrate SUB to the upper surface EMLa of each of the first to third light-emitting layers EML1 to EML3 may be less than the distance l1 from the substrate SUB to the upper surface SCa of the spacer SC.

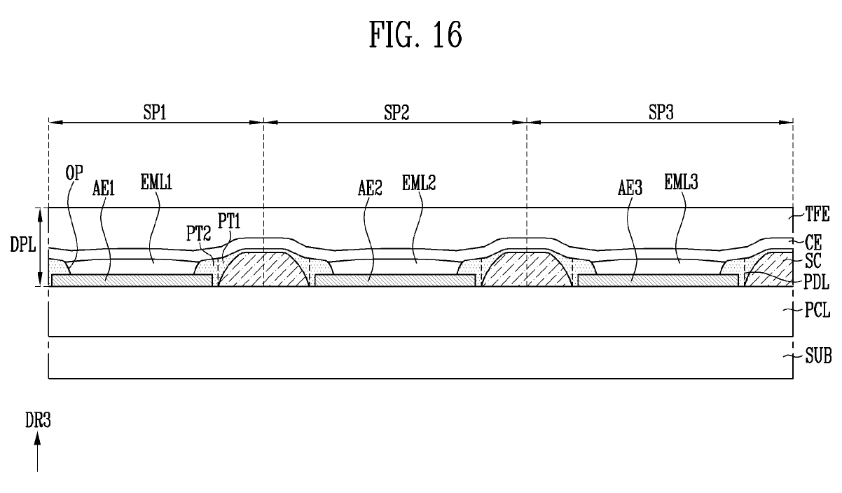

Referring to FIG. 16, the cathode electrode CE may be entirely formed on the pixel defining layer PDL, the spacer SC, and the first to third light-emitting layers EML1 to EML3. The encapsulation layer TFE may be formed entirely on the cathode electrode CE.

In the embodiments, when the light-emitting layers are formed by the inkjet process after the pixel defining layer PDL having liquid repellency is formed on the spacers SC between the first to third sub-pixels SP1 to SP3, the liquid repellency of the surface of the pixel defining layer PDL may prevent the inks constituting the light-emitting layers from flowing over to neighboring sub-pixels. Accordingly, color mixing may be prevented without adding a separate process, so that the reliability of the display device may be improved and the manufacturing efficiency may be improved.

The display device in the embodiment may be applied to various electronic devices. The electronic device in an embodiment may include the above-described display device, and may further include a module or device having an additional function other than the display device.

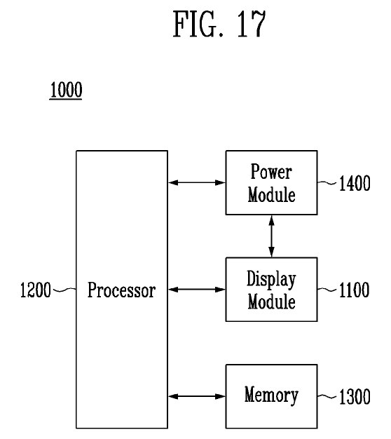

FIG. 17 is a block diagram of an embodiment of an electronic device 1000. Referring to FIG. 1, the electronic device 1000 may include a display module 1100, a processor 1200, a memory 1300, and a power module 1400.

The processor 1200 may include at least one of a central processing unit (“CPU”), an application processor (“AP”), a graphic processing unit (“GPU”), a communication processor (“CP”), an image signal processor (“ISP”), and a controller.

The memory 1300 may store data and/or information used to operate the processor 1200 or the display module 1100. When the processor 1200 executes an application stored in the memory 1300, image data signals and/or input control signals may be transferred to the display module 1100. The display module 1100 may process the provided signals and output image information on a display screen.

The power module 1400 may include a power supply module, such as a power adapter or a battery device, and a power conversion module. The power conversion module converts power supplied by the power supply module and generates power to operate the electronic device 1000.

At least one of the above-described components of the electronic device 1000 may be included in the display device in embodiments as described above. In addition, in terms of functionality, some of the individual modules included in one module may be included in a display device and others may be provided separately from the display device. In an embodiment, the display device may include the display module 1100, and the processor 1200, the memory 1300, and the power module 1400 may be provided as other devices in the electronic device 1000, not the display device, for example.

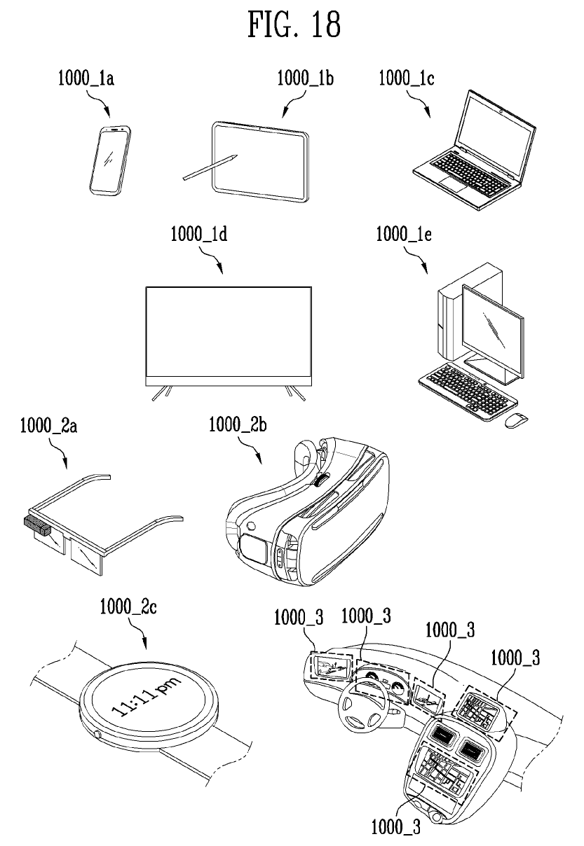

FIG. 18 shows schematic views of various embodiments of the electronic device 1000.

Referring to FIG. 18, various types of electronic devices to which embodiments of a display device are applied may include an electronic device to display images such as a smartphone 1000_1a, a tablet PC 1000_1b, a laptop computer 1000_1c, a television (“TV”) 1000_1d, and a desktop monitor 1000_1e, a wearable electronic device including a display module such as smart glasses 1000_2a, a head-mounted display (“HMD”) 1000_2b, and a smart watch 1000_2c, and an automotive electronic device 1000_3 including a display module such as a center information display (“CID”) disposed at the instrument cluster, the center fascia, and the dashboard of a vehicle, and a room mirror display.

In embodiments of the disclosure, as a pixel defining layer having liquid repellency covers a spacer, first to third light-emitting layers may be prevented from moving over the pixel defining layer to neighboring sub-pixels to cause color mixing. In addition, since a portion of the pixel defining layer which does not overlap the spacer has a height less than that of the spacer, a first portion of the pixel defining layer protrudes from a second portion thereof to serve as the spacer. However, a separate structure or a separate process is not added therefor, so that color mixing is prevented to improve the reliability of the display device, and at the same time, simplify the structure of the display device and improve the manufacturing efficiency thereof.

The disclosure should not be construed as being limited to the embodiments set forth herein. Rather, these embodiments are provided so that this disclosure will be thorough and complete and will fully convey the concept of the disclosure to those skilled in the art.

While the disclosure has been particularly shown and described with reference to embodiments thereof, it will be understood by those of ordinary skill in the art that various changes in form and details may be made therein without departing from the spirit or scope of the disclosure as defined by the following claims.

What is claimed is:

1. A display device comprising:
a substrate;
an anode electrode disposed on the substrate;
a spacer disposed in a same layer as the anode electrode; and
a pixel defining layer defining an opening exposing the anode electrode, the pixel defining layer covering at least a part of the spacer on the spacer,
wherein a liquid repellency of the pixel defining layer is higher than a liquid repellency of the spacer.

2. The display device of claim 1, wherein the pixel defining layer comprises:
a first portion overlapping the spacer in a plan view; and
a second portion formed integrally with the first portion and having a height less than a height of the spacer.

3. The display device of claim 2, wherein a height of the first portion is less than or equal to a maximum height of the second portion.

4. The display device of claim 2, wherein at least a part of a surface of the pixel defining layer includes fluorine.

5. The display device of claim 4, wherein an upper surface of the second portion extending from the first portion has liquid repellency.

6. The display device of claim 1, wherein the spacer is in overall contact with the pixel defining layer.

7. The display device of claim 1, further comprising a light-emitting layer disposed on the anode electrode and disposed in the opening.

8. The display device of claim 7, wherein a distance from the substrate to an upper surface of the spacer is greater than a distance from the substrate to an upper surface of the light-emitting layer.

9. The display device of claim 1, wherein the spacer protrudes further in a thickness direction than the anode electrode.

10. The display device of claim 1, wherein a width of the spacer is less than a width of the pixel defining layer.

11. A method of manufacturing a display device, the method comprising:
forming an anode electrode on a substrate;
forming a spacer in a same layer as the anode electrode; and
defining an opening exposing the anode electrode and forming a pixel defining layer covering at least a part of the spacer on the spacer,
wherein a liquid repellency of the pixel defining layer is higher than a liquid repellency of the spacer.

12. The method of claim 11, wherein the pixel defining layer comprises a first portion and a second portion,
wherein the forming the pixel defining layer comprises:
forming the first portion overlapping the spacer in a plan view; and
forming the second portion integrally with the first portion, the second portion having a height less than a height of the spacer and greater than or equal to a height of the first portion.

13. The method of claim 11, wherein the pixel defining layer includes a material including fluorine.

14. The method of claim 11, wherein the forming the pixel defining layer comprises forming a preliminary pixel defining layer entirely disposed on the substrate and the spacer.

15. The method of claim 14, wherein a height of the preliminary pixel defining layer is less than a height of the spacer.

16. The method of claim 14, wherein the forming the pixel defining layer comprises exposing and developing a portion of the preliminary pixel defining layer overlapping a portion of the anode electrode to form the pixel defining layer defining the opening.

17. The method of claim 11, further comprising, after the forming of the pixel defining layer, forming a light-emitting layer disposed in the opening on the anode electrode.

18. The method of claim 17, wherein the light-emitting layer is formed by an inkjet process.

19. The method of claim 17, wherein a distance from the substrate to an upper surface of the light-emitting layer is less than a distance from the substrate to an upper surface of the spacer.

20. An electronic device comprising:
a processor; and
a display device displaying an image in response to control of the processor, the display device comprising:
a plurality of sub-pixels, each of the plurality of sub-pixels comprising;
an anode electrode disposed on the substrate;
a spacer disposed in a same layer as the anode electrode; and
a pixel defining layer defining an opening exposing the anode electrode and covering at least a part of the spacer on the spacer
wherein sub-pixels emitting light of a same color among the plurality of sub-pixels are arranged in a same column, and
wherein a liquid repellency of the pixel defining layer is higher than a liquid repellency of the spacer.
